(19) United States
(12) Patent Application Publication
(10) Pub. No.: US 2022/0157997 A1
(43) Pub. Date: May 19, 2022

(54) THIN FILM TRANSISTOR, METHOD OF MANUFACTURING THE SAME, DISPLAY PANEL, AND DISPLAY DEVICE

(71) Applicant: ADRC. CO. KR, Seoul (KR)

(72) Inventors: Suhui LEE, Seoul (KR); Hwayeong LEE, Seoul (KR); Youngoo KIM, Seoul (KR); Jiseob LEE, Seoul (KR); Abu Bakar SIDDIK, Seoul (KR); Mohammad Masum BILLAH, Seoul (KR)

(21) Appl. No.: 17/401,467

(22) Filed: Aug. 13, 2021

(30) Foreign Application Priority Data
Nov. 19, 2020 (KR) 10-2020-0155789

(51) Int. Cl. H01L 29/786; H01L 27/12; H01L 29/24; H01L 21/02; H01L 29/66

(52) U.S. Cl. CPC H01L 29/78693; H01L 27/1225; H01L 29/247; H01L 29/66969; H01L 21/02565; H01L 21/02592; H01L 21/02631; H01L 29/78696

(57) ABSTRACT

Disclosed are a method of manufacturing a thin film transistor, a thin film transistor, a display panel, and a display device. The method includes forming a gate electrode, forming an oxide semiconductor layer at least partially overlapping the gate electrode, and forming a source electrode and a drain electrode electrically connected to the oxide semiconductor layer, wherein the forming of the oxide semiconductor layer includes forming a first oxide semiconductor layer, and forming a second oxide semiconductor layer on the first oxide semiconductor layer, the second oxide semiconductor layer having a higher energy bandgap than the first oxide semiconductor layer, wherein the forming of the second oxide semiconductor layer is performed by a different process from the forming of the first oxide semiconductor layer, and the forming of the second oxide semiconductor layer includes spraying a precursor solution for the second oxide semiconductor on the first oxide semiconductor layer followed by heat treatment.

### CROSS-REFERENCE TO RELATED APPLICATION

This application claims priority to and the benefit of Korean Patent Application No. 10-2020-0155789 filed in the Korean Intellectual Property Office on Nov. 19, 2020, the entire contents of which are incorporated herein by reference.

### BACKGROUND OF THE INVENTION

### (a) Field of the Invention

A thin film transistor, a method for manufacturing the same, a display panel, and a display device are disclosed.

### (b) Description of the Related Art

A display device such as a liquid crystal display (LCD) or an organic light emitting diode display (OLED display) includes a thin film transistor (TFT) that is a three-terminal element as a switching element and/or a driving element. Recently, as such a thin film transistor, a thin film transistor including an oxide semiconductor has been studied.

### SUMMARY OF THE INVENTION

An embodiment provides a thin film transistor capable of improving stability and performance.

Another embodiment provides a method of manufacturing the thin film transistor capable of reducing manufacturing cost and improving stability and performance of the thin film transistor without a complicated process.

Another embodiment provides a display panel including the thin film transistor.

Another embodiment provides a display device including the thin film transistor or the display panel.

According to an embodiment, a method of manufacturing a thin film transistor includes forming a gate electrode, forming an oxide semiconductor layer at least partially overlapping the gate electrode, and forming a source electrode and a drain electrode electrically connected to the oxide semiconductor layer, wherein the forming of the oxide semiconductor layer includes forming a first oxide semiconductor layer, and forming a second oxide semiconductor layer on the first oxide semiconductor layer, the second oxide semiconductor layer having a higher energy bandgap than the first oxide semiconductor layer, the forming of the second oxide semiconductor layer is performed by a different process from the forming of the first oxide semiconductor layer, and the forming of the second oxide semiconductor layer includes spraying a precursor solution on the first oxide semiconductor layer followed by heat treatment.

The forming of the first oxide semiconductor layer may be performed by a vapor deposition process.

The heat treatment may be performed at a higher temperature than the forming of the first oxide semiconductor layer.

The heat treatment may be performed at about 250° C. to about 450° C.

The second oxide semiconductor layer may be formed to be thicker than the first oxide semiconductor layer.

The precursor solution may include a zinc precursor and a tin precursor.

The first oxide semiconductor layer may be an indium-gallium-zinc oxide layer, and the second oxide semiconductor layer may be a zinc-tin oxide layer.

According to another embodiment, a thin film transistor includes a gate electrode, an oxide semiconductor layer overlapping the gate electrode, a gate insulating layer between the gate electrode and the oxide semiconductor layer, and a source electrode and a drain electrode electrically connected to the oxide semiconductor layer, wherein the oxide semiconductor layer includes a first oxide semiconductor layer and a second oxide semiconductor layer having a higher energy bandgap than that of the first oxide semiconductor.

The second oxide semiconductor layer may be in contact with an upper surface of the first oxide semiconductor layer, and the first oxide semiconductor layer and the second oxide semiconductor layer may form a heterojunction.

An energy bandgap difference between the second oxide semiconductor layer and the first oxide semiconductor layer may be greater than or equal to about 0.20 eV.

A thickness of an interface between the first oxide semiconductor layer and the second oxide semiconductor layer may be about 0.1 nm to about 0.5 nm.

The first oxide semiconductor layer may be in contact with the gate insulating layer.

The second oxide semiconductor layer may be thicker than the first oxide semiconductor layer.

A thickness of the second oxide semiconductor layer may be about two or more times greater than a thickness of the first oxide semiconductor layer.

A ratio of the thickness of the first oxide semiconductor layer to the thickness of the second oxide semiconductor layer may be about 1:2.5 to about 1:5.

Each of the first oxide semiconductor layer and the second oxide semiconductor layer may be an amorphous semiconductor layer.

The first oxide semiconductor layer may be an indium-gallium-zinc oxide layer, and the second oxide semiconductor layer may be a zinc-tin oxide layer.

According to another embodiment, a display panel including the thin film transistor is provided.

The display panel may include a liquid crystal display panel, an organic light emitting diode display panel, a quantum dot display panel, or a perovskite display panel.

According to another embodiment, a display device including the thin film transistor or the display panel is provided.

Manufacturing costs may be reduced and stability and performance of thin film transistors may be improved without complicated processes.

### BRIEF DESCRIPTION OF THE DRAWINGS

FIG. 1 is a schematic plan view of a thin film transistor according to an embodiment,

FIG. 2 is a cross-sectional view taken along the line II-II′ of FIG. 1,

FIG. 3 is a schematic plan view of a thin film transistor according to another embodiment,

FIG. 4 is a cross-sectional view taken along line IV-IV′ of FIG. 3,

FIG. 5 is a graph showing a transfer curve of the thin film transistor according to Example 1,

FIG. 6 is a graph showing a transfer curve of a thin film transistor according to Comparative Example 1,

FIG. 7 is a graph showing a transfer curve of a thin film transistor according to Comparative Example 2,

FIG. 8 is a graph showing a transfer curve under NBIS of the thin film transistor according to Example 1,

FIG. 9 is a graph showing a transfer curve under NBIS of a thin film transistor according to Comparative Example 1,

FIG. 10 is a graph showing a transfer curve under NBIS of a thin film transistor according to Comparative Example 2,

FIG. 11 is a graph showing a transfer curve under HCS of the thin film transistor according to Example 1,

FIG. 12 is a graph showing a transfer curve under HCS of a thin film transistor according to Comparative Example 1, and

FIG. 13 is a graph showing a transfer curve under HCS of a thin film transistor according to Comparative Example 2.

### DETAILED DESCRIPTION OF THE EMBODIMENTS

Hereinafter, embodiments of the present disclosure will be described in detail so that a person skilled in the art would understand the same. This disclosure may, however, be embodied in many different forms, and is not to be construed as limited to the example embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, “combination” includes a mixture or a stacked structure of two or more.

Hereinafter, a thin film transistor according to an embodiment will be described.

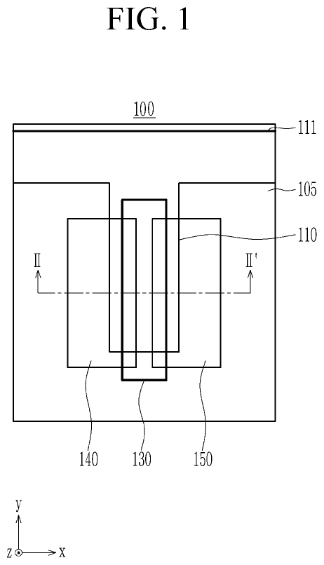

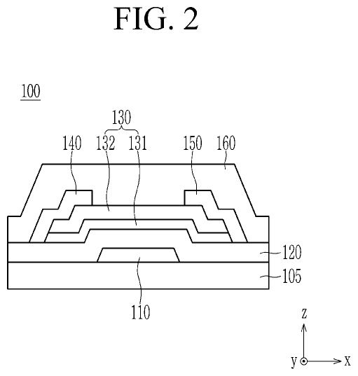

FIG. 1 is a schematic plan view of a thin film transistor according to an embodiment, and FIG. 2 is a cross-sectional view taken along line II-II′ of FIG. 1.

The thin film transistor 100 according to an embodiment includes a gate electrode 110, a gate insulating layer 120, an oxide semiconductor layer 130, a source electrode 140 and a drain electrode 150, and a passivation layer 160.

The substrate 105 may be a supporting substrate that supports the thin film transistor 100, and may be, for example, a glass plate, a polymer substrate, or a silicon wafer. The polymer substrate may include, for example, polyethylene terephthalate, polyethylene naphthalate, polycarbonate, polyacrylate, polymethyl methacrylate, polyimide, polyamide, polyamideimide, a copolymer thereof, or a combination thereof, but is not limited thereto.

The gate electrode 110 is electrically connected to a gate line 111 that transmits a gate signal. The gate electrode 110 may be, for example, made of gold (Au), copper (Cu), nickel (Ni), aluminum (Al), molybdenum (Mo), chromium (Cr), tantalum (Ta), titanium (Ti), an alloy thereof, or a combination thereof, but is not limited thereto. However, when the substrate 105 is a silicon wafer, the gate electrode 110 may be a doped region in the silicon wafer. The gate electrode 110 may have one layer or two or more layers.

The gate insulating layer 120 may be disposed on the gate electrode 110 and cover the whole surface of the substrate 105. The gate insulating layer 120 may include an organic material, an inorganic material, and/or an organic-inorganic material, and may include, for example, an oxide, a nitride, and/or an oxynitride, for example, a silicon oxide, a silicon nitride, a silicon oxynitride, or a combination thereof, but is not limited thereto. The gate insulating layer 120 may be one layer or two or more layers.

The oxide semiconductor layer 130 may be disposed to overlap the gate electrode 110 with the gate insulating layer 120 interposed therebetween. The oxide semiconductor layer 130 may include a channel region of the thin film transistor 100.

The oxide semiconductor layer 130 includes a first oxide semiconductor layer 131 and a second oxide semiconductor layer 132. The first oxide semiconductor layer 131 and the second oxide semiconductor layer 132 are stacked in the thickness direction (e.g., z-direction) of the substrate 105. For example, the first oxide semiconductor layer 131 may be in contact with the gate insulating layer 120 and the second oxide semiconductor layer 132 may be in contact with the upper surface of the first oxide semiconductor layer 131.

The first oxide semiconductor layer 131 and the second oxide semiconductor layer 132 may include an oxide semiconductor having different electrical characteristics and may be formed by different processes. Accordingly, the first oxide semiconductor layer 131 and the second oxide semiconductor layer 132 may have different characteristics.

The first oxide semiconductor layer 131 may be disposed close to the gate electrode 110 and may be disposed in contact with the gate insulating layer 120 to form a main channel of the thin film transistor 100.

The first oxide semiconductor layer 131 may have relatively high conductivity. For example, the energy bandgap of the first oxide semiconductor layer 131 may be less than or equal to about 3.5 eV, and may be about 3.0 eV to about 3.5 eV, about 3.1 eV to about 3.4 eV, or about 3.1 eV to about 3.3 eV. For example, the electron affinity of the first oxide semiconductor layer 131 may be less than or equal to about 4.3 eV, and may be about 4.0 eV to about 4.3 eV or about 4.1 eV to about 4.3 eV.

The first oxide semiconductor layer 131 may have a relatively low density of charge traps. For example, the density of the charge traps of the first oxide semiconductor layer 131 may be less than or equal to about 50×10¹¹ cm⁻²eV⁻¹, within the above range, less than or equal to about 45.0×10¹¹ cm⁻²eV⁻¹, or less than or equal to about 44.0×10¹¹ cm⁻²eV⁻¹, and within the above range, about 1.0×10¹¹ cm⁻²eV⁻¹ to about 50×10¹¹ cm²ev⁻¹, about 1.0×10¹¹ cm⁻²eV⁻¹ to about 45.0×10¹¹ cm⁻²eV⁻¹, about 1.25×10¹¹ cm⁻²eV⁻¹ to about 45.0×10¹¹ cm⁻²eV⁻¹, or about 1.25×10¹¹ cm⁻²ev⁻¹ to about 44.0×10¹¹ cm⁻²eV⁻¹.

Since the first oxide semiconductor layer 131 is formed by a vapor deposition process as will be described later, it may be formed as a dense film. The first oxide semiconductor layer 131 may have a relatively thin thickness, for example, the first oxide semiconductor layer 131 may have a thickness of less than or equal to about 20 nm, less than or equal to about 15 nm, less than or equal to about 12 nm, or less than or equal to about 10 nm, and within the above range, about 2 nm to about 20 nm, about 2 nm to about 15 nm, about 2 nm to about 12 nm, or about 2 nm to about 10 nm.

The second oxide semiconductor layer 132 is separated from the gate insulating layer 120 and may form a sub-channel or an auxiliary channel of the thin film transistor 100.

The second oxide semiconductor layer 132 may have a larger energy bandgap than the first oxide semiconductor layer 131, and an energy bandgap difference between the second oxide semiconductor layer 132 and the first oxide semiconductor layer 131 may be for example greater than or equal to about 0.20 eV, within that range, greater than or equal to about 0.25 eV, greater than or equal to about 0.28 eV, greater than or equal to about 0.30 eV, or greater than or equal to about 0.32 eV, and within the above range, about 0.20 eV to about 0.5 eV, about 0.25 eV to about 0.5 eV, about 0.28 eV to about 0.5 eV, about 0.30 eV to about 0.5 eV, or about 0.32 eV to about 0.5 eV. For example, the energy bandgap of the second oxide semiconductor layer 132 may be greater than or equal to about 3.3 eV, and may be about 3.3 eV to about 4.0 eV, about 3.4 eV to about 3.9 eV, or about 3.4 eV to about 3.8 eV.

The second oxide semiconductor layer 132 may have a greater electron affinity than the first oxide semiconductor layer 131, and for example, an electron affinity difference between the second oxide semiconductor layer 132 and the first oxide semiconductor layer 131 may be greater than or equal to about 0.10 eV, and within the above range, about 0.10 eV to about 0.40 eV or about 0.10 eV to about 0.30 eV. For example, the electron affinity of the second oxide semiconductor layer 131 may be greater than or equal to about 4.2 eV, and may be about 4.2 eV to about 4.5 eV or about 4.3 eV to about 4.5 eV.

The density of the charge traps of the second oxide semiconductor layer 132 may be higher than the density of the charge traps of the first oxide semiconductor layer 131. For example, the density of the charge traps of the second oxide semiconductor layer 132 is at least about 1.1 times, at least about 1.2 times, at least about 1.3 times, at least about 1.5 times, at least about 1.8 times, or at least about 2 times, and within the above range, about 1.1 times to about 10 times, about 1.2 times to about 10 times, about 1.3 times to about 10 times, about 1.5 times to about 10 times, about 1.8 times to about 10 times, or about 2 times to about 10 times greater than the density of the charge traps of the first oxide semiconductor layer 131. For example, the density of the charge traps of the second oxide semiconductor layer 132 may be greater than or equal to about 1.0×10¹¹ cm⁻²eV⁻¹, and within the above range, about 1.0×10¹¹ cm⁻²eV⁻¹ to about 50×10¹¹ cm⁻²eV⁻¹, about 1.0×10¹¹ cm⁻²eV⁻¹ to about 45×10¹¹ cm⁻²eV⁻¹, about 1.25×10¹¹ cm⁻²eV⁻¹ to about 50×10¹¹ cm⁻²eV⁻¹, about 1.25×10¹¹ cm⁻²eV⁻¹ to about 45×10¹¹ cm⁻²eV⁻¹, or about 1.25×10¹¹ cm⁻²eV⁻¹ to about 44.32×10¹¹ cm⁻²eV⁻¹.

The second oxide semiconductor layer 132 may be thicker than the first oxide semiconductor layer 131. For example, the thickness of the second oxide semiconductor layer 132 may be about twice or more that of the first oxide semiconductor layer 131. For example, a ratio of the thickness of the first oxide semiconductor layer 131 to the thickness of the second oxide semiconductor layer 132 may be about 1:2.5 to about 1:5, and within the above range, about 1:2.5 to about 1:4.5 or about 1:2.5 to about 1:3.5. For example, the thickness of the second oxide semiconductor layer 132 may be greater than or equal to about 15 nm, greater than or equal to about 20 nm, or greater than or equal to about 25 nm, within the above range, may be about 15 nm to about 50 nm, about 20 nm to about 50 nm, or about 25 nm to about 50 nm.

Also, the second oxide semiconductor layer 132 may be disposed on the first oxide semiconductor layer 131 to serve as a protective layer of the first oxide semiconductor layer 131. Accordingly, the first oxide semiconductor layer 131 is prevented from being damaged in a subsequent process such as forming the source electrode 140 and the drain electrode 150 without a separate etch stopper, and thus deterioration of the performance of the thin film transistor 100 may be prevented.

The second oxide semiconductor layer 132 may be disposed on the upper surface of the first oxide semiconductor layer 131. For example, the upper surface of the first oxide semiconductor layer 131 and the lower surface of the second oxide semiconductor layer 132 may contact each other to form an interface. Accordingly, the first oxide semiconductor layer 131 and the second oxide semiconductor layer 132 may form a heterojunction, and the stability of the thin film transistor 100 may be improved by high charge distribution due to the heterojunction of the first oxide semiconductor layer 131 and the second oxide semiconductor layer 132.

In particular, the oxide semiconductor layer 130 including the first oxide semiconductor layer 131 and the second oxide semiconductor layer 132 may have improved stability compared to a single-layered semiconductor layer of the first oxide semiconductor layer 131 or the second oxide semiconductor layer 132, under negative gate bias illumination stress (NBIS) and hot carrier stress (HCS).

In general, in a thin film transistor including an oxide semiconductor, a high threshold voltage shift (ΔVₜₕ) under NBIS may be caused by electron-hole pair generation and subsequent migration of holes to the interface between the oxide semiconductor layer and the gate insulating layer. On the other hand, the oxide semiconductor layer 130 including the first oxide semiconductor layer 131 and the second oxide semiconductor layer 132 having the aforementioned characteristics may reduce a threshold voltage shift by dispersion of charge shifts to the interface between the first oxide semiconductor layer 131 and the second oxide semiconductor layer 132 and the interface between the first oxide semiconductor 131 and the gate insulating layer 120, as well as high charge separation due to the heterojunction of the first oxide semiconductor layer 131 and the second oxide semiconductor layer 132.

Moreover, as described above, electrons may effectively move from the second oxide semiconductor layer 132 to the first oxide semiconductor layer 131 by the difference in electron affinity between the first oxide semiconductor layer 131 and the second oxide semiconductor layer 132 and the defects concentrated on the surface of the first oxide semiconductor layer 131 (e.g., oxygen cavities), so that high reliability can be achieved under NBIS.

Also, in general, in a thin film transistor including an oxide semiconductor, the high change in the subthreshold swing (ΔSS) and the high threshold voltage shift (ΔVₜₕ) under the HCS condition may be caused by a large depletion region near the drain electrode and a concentrated electric field under the HCS condition. On the other hand, the oxide semiconductor layer 130 including the first oxide semiconductor layer 131 and the second oxide semiconductor layer 132 having the aforementioned characteristics may greatly reduce the depletion region near the drain electrode and effectively disperse the concentrated electric field, thereby effectively reducing the change in the subthreshold swing (ΔSS) and the threshold voltage shift (ΔVₜₕ). In addition, electrons are dispersed and accumulated at the interface of the first oxide semiconductor layer 131 and the gate insulating layer 120 and the interface of the first oxide semiconductor layer 131 and the second oxide semiconductor layer 132 under HCS, and thereby high reliability of the thin film transistor under HCS may be exhibited.

Meanwhile, the interface between the first oxide semiconductor layer 131 and the second oxide semiconductor layer 132 may have a predetermined thickness, and the predetermined thickness may be, for example, formed so that the second oxide semiconductor layer 132 may fill the defects in the surface of the first semiconductor layer 131 and between bumps (unevenness) of the upper surface of the first oxide semiconductor layer 131.

For example, the surface bumps (unevenness) of the upper surface of the first oxide semiconductor layer 131 may be intentionally or unintentionally formed in a vapor deposition process. As will be described later, since the second oxide semiconductor layer 131 is formed on the first oxide semiconductor layer 131 by a spray process, the solution supplied from the spray process may effectively fill the defects in the surface of the first semiconductor layer 131 and between the bumps (unevenness) of the upper surface of the first oxide semiconductor layer 131.

Accordingly, the interface between the first oxide semiconductor layer 131 and the second oxide semiconductor layer 132 may be formed to have a thickness equal to, for example, the surface roughness of the first oxide semiconductor layer 131. For example, the thickness of the interface between the first oxide semiconductor layer 131 and the second oxide semiconductor layer 132 may be about 0.1 nm to about 0.5 nm, and within the above range, about 0.1 nm to about 0.4 nm, about 0.2 nm to about 0.4 nm, or about 0.2 nm to about 0.3 nm, but is not limited thereto. Accordingly, by improving the interface characteristics of the first oxide semiconductor layer 131 and the second oxide semiconductor layer 132, the stability and performance of the thin film transistor 100 may be improved.

The first oxide semiconductor layer 131 and the second oxide semiconductor layer 132 may be a combination satisfying the aforementioned characteristics, for example, the first oxide semiconductor layer 131 may be an indium-gallium-zinc oxide layer (In—Ga—Zn oxide layer) and the second oxide semiconductor layer 132 may be a zinc-tin oxide layer (Zn—Sn oxide layer).

For example, the indium-gallium-zinc oxide layer may be an oxide layer made of indium (In), gallium (Ga), and zinc (Zn) as a metal element.

For example, the indium-gallium-zinc oxide layer may be an oxide layer including indium (In), gallium (Ga), and zinc (Zn) as main components, and one or more other elements (e.g., metals or semimetals) in addition to indium (In), gallium (Ga), and zinc (Zn) may further be included as dopants.

For example, the zinc-tin oxide layer may be an oxide layer made of zinc (Zn) and tin (Sn) as metal elements.

For example, the zinc-tin oxide layer may be an oxide layer including zinc (Zn) and tin (Sn) as main components, and other elements (e.g., metals or semimetals) may be included as dopants in addition to zinc (Zn) and tin (Sn).

The first oxide semiconductor layer 131 and the second oxide semiconductor layer 132 may each be an amorphous semiconductor layer, for example, the first oxide semiconductor layer 131 may be an amorphous indium-gallium-zinc oxide layer and the second oxide semiconductor layer 132 may be an amorphous zinc-tin oxide layer.

For example, the oxide semiconductor layer 130 may have a bi-layer structure including the first oxide semiconductor layer 131 and the second oxide semiconductor layer 132.

For example, the oxide semiconductor layer 130 may further include an additional layer in addition to the first oxide semiconductor layer 131 and the second oxide semiconductor layer 132.

The source electrode 140 and the drain electrode 150 may be disposed on the oxide semiconductor layer 130, specifically, on the second oxide semiconductor layer 132. The source electrode 140 and the drain electrode 150 may face each other in the center of the oxide semiconductor layer 130, and may be electrically connected to the oxide semiconductor layer 130. The source electrode 140 may be electrically connected to a data line (not shown) that transmits a data signal, and the drain electrode 150 may have an island shape. The source electrode 140 and the drain electrode 150 may be, for example, made of gold (Au), copper (Cu), nickel (Ni), aluminum (Al), molybdenum (Mo), chromium (Cr), tantalum (Ta), titanium (Ti), an alloy thereof, or a combination thereof, but is not limited thereto.

The passivation layer 160 may be disposed on the source electrode 140 and the drain electrode 150, and may protect and planarize the thin film transistor 100. The passivation layer 160 may include an organic material, an inorganic material, and/or an organic-inorganic material, and may include, for example, an oxide, a nitride, and/or an oxynitride, for example, a silicon oxide, a silicon nitride, a silicon oxynitride, or a combination thereof, but is not limited thereto. The passivation layer 160 may be one layer or two or more layers.

As described above, the thin film transistor 100 includes a first oxide semiconductor layer 131 and a second oxide semiconductor layer 132 formed by different processes and including oxide semiconductors having different electrical characteristics, and thus the stability and performance of the thin film transistor 100 may be improved by supplementing the characteristics of the thin film transistor including the oxide semiconductor.

Specifically, the first oxide semiconductor layer 131 may exhibit high field effect mobility as a main channel of the thin film transistor 100 by forming a dense and thin oxide semiconductor having high conductivity, and the second oxide semiconductor layer 132 may be formed on the upper surface of the first oxide semiconductor layer 131 by a spraying process to enhance the interfacial properties with the first oxide semiconductor layer 131, thereby effectively forming a heterojunction with the first oxide semiconductor layer 131 and thus enhancing the charge separation characteristics. Accordingly, while increasing the field effect mobility of the thin film transistor 100, the subthreshold swing (SS), negative gate bias illumination stress (NBIS), hot carrier stress (HCS), and short channel effect may be effectively improved.

Hereinafter, a method for manufacturing the above-described thin film transistor will be described.

A method of manufacturing a thin film transistor according to an embodiment includes forming a gate electrode 110 on a substrate 105, forming a gate insulating layer 120, forming an oxide semiconductor layer 130, forming a source electrode 140 and the drain electrode 150, and forming a passivation layer 160.

The gate electrode 110 may be formed by depositing, for example, vapor deposition such as sputtering gold (Au), copper (Cu), nickel (Ni), aluminum (Al), molybdenum (Mo), chromium (Cr), tantalum (Ta), titanium (Ti), an alloy thereof, or a combination thereof, followed by patterning the resultant.

The gate insulating layer 120 may be formed on the whole surface of the substrate 105 including the gate electrode 110, and may be formed by chemical vapor deposition of, for example, an oxide, a nitride, an oxynitride, and/or organic material. The gate insulating layer 120 may be formed in one or two or more layers, and may include, for example, an oxide layer made of an oxide such as a silicon oxide and a nitride layer made of a nitride such as a silicon nitride.

The forming of the oxide semiconductor layer 130 may include forming the first oxide semiconductor layer 131 on the gate insulating layer 120 and forming the second oxide semiconductor layer 132 on the first oxide semiconductor layer 131. Optionally, the method may further include surface-treating the upper surface of the first oxide semiconductor layer 131 before forming the second oxide semiconductor layer 132. The first oxide semiconductor layer 131 and the second oxide semiconductor layer 132 may be formed to have substantially the same planar shape and may be formed to be at least partially overlapped with the gate electrode 110.

The first oxide semiconductor layer 131 may be performed, for example, by vapor deposition, such as sputtering, vacuum deposition, chemical vapor deposition, physical vapor deposition, atomic layer deposition, metal organic chemical vapor deposition, plasma-enhanced chemical vapor deposition, molecular beam epitaxy, hydride vapor phase epitaxy, or pulsed laser deposition. For example, the forming of the first oxide semiconductor layer 131 may be performed by sputtering such as radio frequency sputtering (RF sputtering).

The first oxide semiconductor layer 131 may be formed, for example, at a temperature of less than about 250° C., for example greater than or equal to about 50° C. and less than about 250° C., greater than or equal to about 80° C. and less than about 250° C., greater than or equal to about 100° C. and less than about 250° C., or greater than or equal to about 150° C. and less than about 250° C.

The first oxide semiconductor layer 131 may be, for example, an indium-gallium-zinc oxide layer.

The forming of the second oxide semiconductor layer 132 may be performed by a different process from the forming of the first oxide semiconductor layer 131, and may be, for example, performed by a spray process, for example, by spray pyrolysis. Such a spraying process may be performed in a non-vacuum atmosphere such as air, for example, and has advantages of low process cost and high throughput in a large area, as well as being applied to the surface of the first oxide semiconductor layer 131 to exhibit the aforementioned interface characteristics, thereby effectively improving the stability and performance of the thin film transistor 100.

The forming of the second oxide semiconductor layer 132 may include spraying a precursor solution on the first oxide semiconductor layer 131 and performing heat treatment. The heat treatment may be performed by performing a separate heat treatment after spraying, or by increasing the temperature of the substrate 105 and/or the temperature of the chamber to a predetermined temperature during the spraying process.

The precursor solution may include a precursor for an oxide semiconductor, for example, a zinc precursor and a tin precursor.

The zinc precursor may be, for example, a zinc salt, a zinc hydroxide, a zinc alkoxide, a hydrate thereof, or a combination thereof, for example zinc acetate, zinc acetate dihydrate, zinc chloride, zinc chloride hydrate, zinc fluoride, zinc fluoride hydrate, zinc acetylacetonate hydrate, zinc acrylate, zinc nitrate, zinc nitride, a hydrate thereof, or a combination thereof, but is not limited thereto.

The tin precursor may be, for example, a tin salt, a tin hydroxide, a tin alkoxide, a hydrate thereof, or a combination thereof, for example tin chloride, tin chloride hydrate, tin bromide, tin iodide, tin fluoride, tin fluoride hydrate, tin acetate, tin acetate dihydrate, tin acetylacetonate hydrate, tin acetylacetonate hydrate, tin nitrate, tin nitride, a hydrate thereof, or a combination thereof, but is not limited thereto.

A ratio of the zinc precursor and the tin precursor may be determined according to a desired atomic ratio of zinc and tin included in the second oxide semiconductor layer 132 in consideration of electrical properties of the second oxide semiconductor layer 132, and may be, for example, a mole ratio of about 1:10 to about 10:1, about 2:8 to about 8:2, about 3:7 to about 7:3, about 4:6 to about 6:4, or about 5:5, but is not limited thereto.

The zinc precursor and the tin precursor may be included in an amount of about 0.1 wt % to about 50 wt %, respectively, based on the precursor solution, and may be included in an amount of about 1 wt % to about 40 wt % or about 5 wt % to about 30 wt % within the above range.

The precursor solution may optionally further include a solution stabilizer. The solution stabilizer may include at least one selected from, for example, an ammonium salt, an alcohol amine compound, an alkyl ammonium hydroxy compound, an alkyl amine compound, a ketone compound, an acid compound, and a base compound, for example, ammonium acetate, ammonium hydroxide, monoethanolamine, diethanolamine, triethanolamine, monoisopropylamine, N,N-methylethanolamine, aminoethyl ethanolamine, diethylene glycolamine, 2-(aminoethoxy)ethanol, N-t-butylethanolamine, N-t-butyldiethanolamine, tetramethylammoniumhydroxide, methylamine, ethylamine, acetylacetone, hydrochloric acid, nitric acid, sulfuric acid, acetic acid, potassium hydroxide, sodium hydroxide, or a combination thereof, but is not limited thereto. The solution stabilizer may be included in an amount of about 0.01 wt % to about 30 wt % based on the precursor solution.

The zinc precursor, the tin precursor, and optionally the solution stabilizer may be mixed in a solvent to prepare a precursor solution. At this time, the zinc precursor and the tin precursor may be prepared by preparing each solution in a solvent, and then by mixing these solutions as a precursor solution, or may be prepared as a precursor solution by mixing the zinc precursor and the tin precursor together in a solvent.

The solvent is not particularly limited as long as it can dissolve the above components, and may be, for example, selected from methanol, ethanol, propanol, isopropanol, 2-methoxyethanol, 2-ethoxyethanol, 2-propoxyethanol 2-butoxyethanol, methylcellosolve, ethylcellosolve, diethylene glycolmethylether, diethylene glycolethylether, dipropylene glycolmethylether, toluene, xylene, hexane, heptane, octane, ethylacetate, butylacetate, diethylene glycoldimethylether, diethylene glycoldimethylethylether, methyl ethoxy propionate, ethyl ethoxy propionate, ethyl lactate, propylene glycolmethyletheracetate, propylene glycolmethylether, propylene glycolpropylether, methylcellosolve acetate, ethylcellosolve acetate, diethylene glycolmethylacetate, diethylene glycolethylacetate, acetone, methylisobutylketone, cyclohexanone, dimethyl formamide (DMF), N,N-dimethyl acetamide (DMAc), N-methyl-2-pyrrolidone, γ-butyrolactone, diethylether, ethylene glycoldimethylether, diglyme, tetrahydrofuran, acetylacetone, acetonitrile, or a combination thereof, but is not limited thereto.

The precursor solution may be stirred at, for example, a predetermined temperature. For example, after stirring at a temperature of about 30° C. to about 60° C., filtering may be further performed.

Then, the prepared precursor solution may be sprayed on the first oxide semiconductor layer 131 to form a precursor layer. In the spraying process, the substrate temperature may be about 250° C. to about 450° C., and for example, it may be performed in an air atmosphere. The spraying time and interval may be varied in consideration of the concentration of the precursor solution and the thickness to be formed, and the spraying may be, for example, performed at once or at predetermined intervals for about 1 second to about 100 seconds. The precursor layer may be thicker than the desired thickness of the second oxide semiconductor layer 132, and the precursor layer may be, for example, formed to have a thickness of about 30 nm to about 200 nm.

Subsequently, the precursor layer may be heat-treated to form the second oxide semiconductor layer 132. The heat treatment may be performed, for example, at a higher temperature than the forming temperature of the first oxide semiconductor layer 131, for example, at a temperature of about 250° C. to about 500° C. or about 300° C. to about 400° C. Alternatively, instead of a separate heat treatment, the temperature of the substrate 105 and/or the temperature of the chamber may be increased to a temperature of, for example, about 250° C. to about 500° C. or about 300° C. to about 400° C. in the spraying process. As described above, the second oxide semiconductor layer 132 obtained by spray pyrolysis may be formed to be thicker than the first oxide semiconductor layer 131, and may be formed to be about twice as thick.

The second oxide semiconductor layer 132 may be, for example, a zinc-tin oxide layer.

The source electrode 140 and the drain electrode 150 may be formed by vapor deposition, such as sputtering of gold (Au), copper (Cu), nickel (Ni), aluminum (Al), molybdenum (Mo), chromium (Cr), tantalum (Ta), titanium (Ti), an alloy thereof, or a combination thereof on the second oxide semiconductor layer 132, and then patterning the resultant. In this case, the second oxide semiconductor layer 132 may effectively protect the first oxide semiconductor layer 131 during the deposition and/or patterning of the source electrode 140 and the drain electrode 150, thereby preventing damages of the first oxide semiconductor layer 131.

The passivation layer 160 may be formed on the source electrode 140 and the drain electrode 150 by chemical vapor deposition of, for example, an oxide, a nitride, an oxynitride, and/or an organic material. The passivation layer 160 may be formed in one or two or more layers, and may include, for example, an oxide layer made of an oxide such as a silicon oxide and a nitride layer made of a nitride such as a silicon nitride.

As described above, the thin film transistor 100 includes the first oxide semiconductor layer 131 formed by the vapor deposition process and the second oxide semiconductor layer 132 formed by the spray process, thereby effectively improving the stability and performance of the thin film transistor 100. Specifically, as described above, the first oxide semiconductor layer 131 may exhibit high field effect mobility by forming a high-conductivity oxide semiconductor thinly and densely by a vapor deposition process, and the second oxide semiconductor layer 132 is formed on the upper surface of the first oxide semiconductor layer 131 by a spray process, thereby effectively reducing or removing defects at the surface of the first oxide semiconductor layer 131, and at the same time, enhancing interfacial characteristics with the first oxide semiconductor layer 131 to effectively improve subthreshold swing, NBIS, HCS, and short channel effect.

Hereinafter, a thin film transistor according to another embodiment will be described.

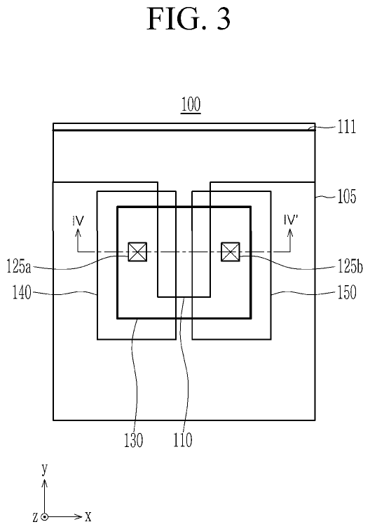

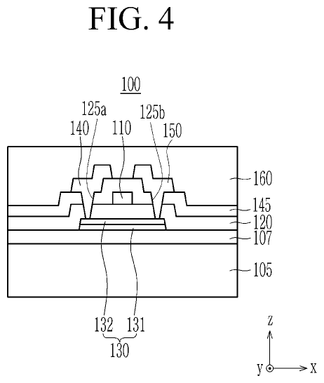

FIG. 3 is a schematic plan view of a thin film transistor according to another embodiment, and FIG. 4 is a cross-sectional view taken along line IV-IV′ of FIG. 3.

The thin film transistor 100 according to the present embodiment includes a gate electrode 110, a gate insulating layer 120, an oxide semiconductor layer 130, a source electrode 140 and a drain electrode 150, and a passivation layer 160, like the aforementioned embodiment.

However, the thin film transistor 100 according to the present embodiment may have a structure of a co-planar thin film transistor, unlike the aforementioned embodiment.

The substrate 105 may be a supporting substrate that supports the thin film transistor 100, and may be a glass plate, a polymer substrate, or a silicon wafer as described above.

A buffer layer 107 is formed on the substrate 105. The buffer layer 107 may include an organic material, an inorganic material, or an organic-inorganic material. The buffer layer 107 may include, for example, an oxide, a nitride, or an oxynitride, and may include, for example, a silicon oxide, a silicon nitride, a silicon oxynitride, or a combination thereof. However, the present disclosure is not limited thereto. The buffer layer 107 may be one or two or more layers, and may cover the entire surface of the substrate 105. The buffer layer 107 may be omitted.

The oxide semiconductor layer 130 is formed on the buffer layer 107, and the oxide semiconductor layer 130 includes the first oxide semiconductor layer 131 and the second oxide semiconductor layer 132 as described above. As described above, the first oxide semiconductor layer 131 and the second oxide semiconductor layer 132 may include oxide semiconductors having different electrical characteristics and may be formed by different processes, and detailed descriptions thereof are as described above. The oxide semiconductor layer 130 may include a channel region overlapped with the gate electrode 110 and a doped region disposed at both sides of the channel region and electrically connected to the source electrode 140 and the drain electrode 150, respectively.

The gate insulating layer 120 and the gate electrode 110 are formed on the oxide semiconductor layer 130. The gate electrode 110 is electrically connected to the gate line 111, and detailed descriptions thereof are the same as described above.

An interlayer insulating layer 145 is formed on the gate insulating layer 120 and the gate electrode 110. The interlayer insulating layer 145 may include an organic material, an inorganic material, or an organic-inorganic material, and may include, for example, an oxide, a nitride, or an oxynitride, for example, a silicon oxide, a silicon nitride, a silicon oxynitride, or a combination thereof, but is not limited thereto. The interlayer insulating layer 145 may have one layer or two or more layers. The gate insulating layer 120 and the interlayer insulating layer 145 have contact holes 125a and 125b exposing the oxide semiconductor layer 130, respectively.

A source electrode 140 and a drain electrode 150 are formed on the interlayer insulating layer 145. The source electrode 140 and the drain electrode 150 may be electrically connected to the doped region of the oxide semiconductor layer 130 through the contact holes 125a and 125b. The passivation layer 160 is formed on the source electrode 140 and the drain electrode 150, and detailed descriptions thereof are the same as described above.

The thin film transistor 100 according to this embodiment also includes the first oxide semiconductor layer 131 and the second oxide semiconductor layer 132 which are formed by different processes and include an oxide semiconductor having different electrical characteristics, and thereby the characteristics of the thin film transistor including the oxide semiconductors may be supplemented to improve stability and performance of the thin film transistor 100.

The aforementioned thin film transistor 100 may be included in various display panels, for example, a liquid crystal display (LCD) panel, an organic light emitting diode (OLED) display panel, a quantum dot light emitting diode (QD-LED) display panel, or a perovskite display panel.

The aforementioned thin film transistor or display panel may be included in various electronic devices, and for example, may be included in a display device or a semiconductor device.

Hereinafter, the embodiments are illustrated in more detail with reference to examples. However, the following examples are for illustrative purposes and do not limit the scope of claims.

### PREPARATION EXAMPLE: PREPARATION OF PRECURSOR SOLUTION

Zinc acetate dihydrate (Zn(CH₃CO₂)₂, Sigma Aldrich Co., Ltd.), tin chloride (SnCl₂, Sigma Aldrich Co., Ltd.), and ammonium acetate (CH₃CO₂NH₄, Sigma Aldrich Co., Ltd.) are mixed in a mole ratio of 4:1:1 in 2-methoxyethanol and then stirred on a hot plate for 2 hours and filtered through 0.45 μm polytetrafluoroethylene (PTFE), obtaining a precursor solution for zinc tin oxide.

### Manufacture of Thin Film Transistor

### EXAMPLE 1

A 100 nm-thick molybdenum layer is formed on a glass substrate through sputtering and then patterned to form a gate electrode. Subsequently, a 100 nm-thick silicon nitride (SiNₓ) layer and a 150 nm-thick silicon oxide SiO₂ layer are sequentially deposited on the gate electrode through chemical vapor deposition (PECVD) to form a gate insulating layer. Subsequently, indium-gallium-zinc oxide is deposited on the gate insulating layer through RF sputtering at 200° C. to form an 10 nm-thick indium-gallium-zinc oxide semiconductor layer (a first oxide semiconductor layer, an energy bandgap: 3.24 eV, electronic affinity: 4.16 eV). Subsequently, the precursor solution according to Preparation Example is sprayed on the first oxide semiconductor layer under an air atmosphere and then heat-treated at 350° to form a 30 nm-thick zinc-tin oxide semiconductor layer (a second oxide semiconductor layer, energy bandgap: 3.61 eV, electronic affinity: 4.38 eV). Subsequently, the first oxide semiconductor layer and the second oxide semiconductor layer are patterned, forming a double-layered oxide semiconductor layer. On the oxide semiconductor layer, a 150 nm-thick molybdenum layer is formed through sputtering to form a source electrode and a drain electrode. Subsequently, a 300 nm-thick silicon oxide SiO₂ layer is formed thereon through chemical vapor deposition (CVD) to form a passivation layer, and then annealed under vacuum at 250° C. for 4 hours, manufacturing a thin film transistor. A channel length (L) and a channel width (W) of the thin film transistor are about 2 μm and about 20 μm, respectively.

### COMPARATIVE EXAMPLE 1

A thin film transistor is manufactured according to the same method as Example 1, except that the first oxide semiconductor layer alone is formed without the second oxide semiconductor layer as the oxide semiconductor layer.

### COMPARATIVE EXAMPLE 2

A thin film transistor is manufactured according to the same method as Example 1, except that the second oxide semiconductor layer alone is formed without the first oxide semiconductor layer as the oxide semiconductor layer.

### Evaluation I

Field effect mobility (μ_{FE}), subthreshold swing (SS), and threshold voltage (Vₜₕ) of the thin film transistors according to Examples and Comparative Examples are evaluated.

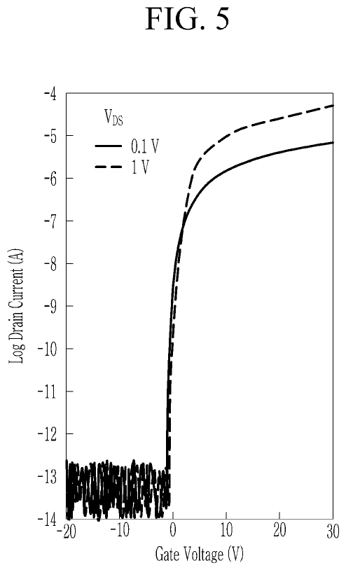

The results are shown in Table 1 and FIGS. 5 to 7.

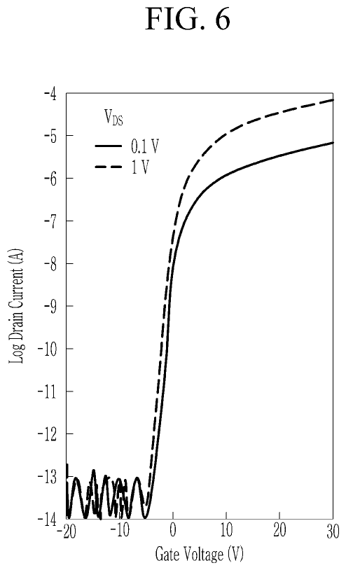

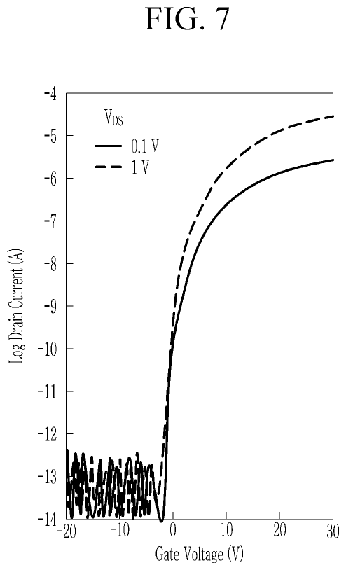

FIG. 5 is a graph showing a transfer curve of the thin film transistor according to Example 1, FIG. 6 is a graph showing a transfer curve of a thin film transistor according to Comparative Example 1, and FIG. 7 is a graph showing a transfer curve of a thin film transistor according to Comparative Example 2.

TABLE 1

| | μ_{FE} (cm²/V · s) | SS (V/dec) | Vₜₕ (V) |
|---|---|---|---|
| Example 1 | 18.39 | 0.16 | 0.1 |
| Comparative Example 1 | 19.72 | 0.94 | −1.2 |
| Comparative Example 2 | 10.32 | 0.79 | 0.3 |

Referring to Table 1 and FIGS. 5 to 7, the thin film transistor according to Example exhibits similar field effect mobility (μ_{FE}) to that of the thin film transistor according to Comparative Example 1 and also greatly improved subthreshold swing (SS) and threshold voltage (Vₜₕ), compared with those of the thin film transistors according to Comparative Examples 1 and 2.

### Evaluation II

Current characteristics of the thin film transistors according to Examples and Comparative Examples are evaluated under NBIS (negative gate bias illumination stress).

NBIS condition: a 10,000 nit white light source at a gate bias (VGs) of −20 V

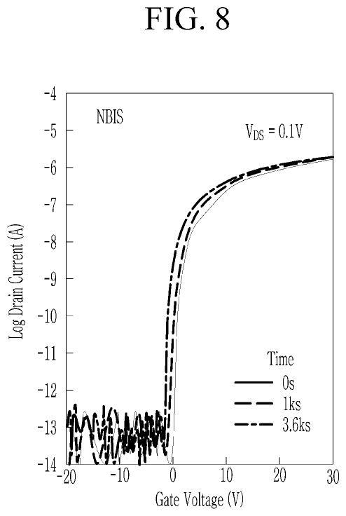

The results are shown in Table 2 and FIGS. 8 to 10.

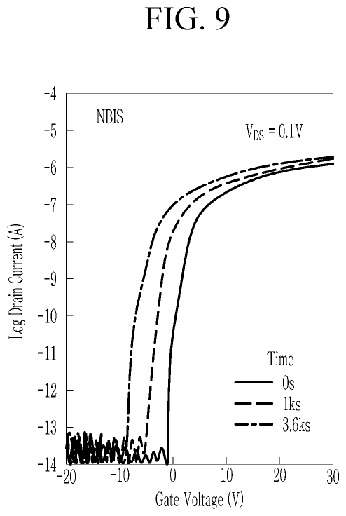

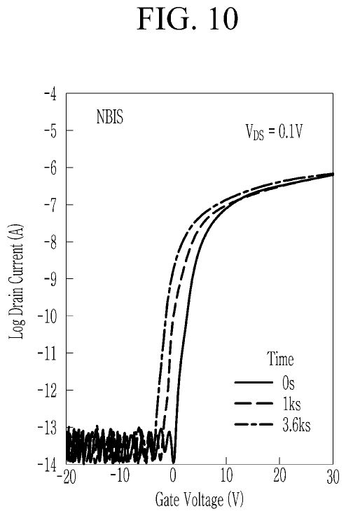

FIG. 8 is a graph showing a transfer curve under NBIS of the thin film transistor according to Example 1, FIG. 9 is a graph showing a transfer curve under NBIS of a thin film transistor according to Comparative Example 1, and FIG. 10 is a graph showing a transfer curve under NBIS of a thin film transistor according to Comparative Example 2.

TABLE 2

| | ΔVₜₕ (V) |
|---|---|
| Example 1 | −1.0 |
| Comparative Example 1 | −7.1 |
| Comparative Example 2 | −3.6 |

Referring to Table 2 and FIGS. 8 to 10, the transistor thin film according to Example exhibits an improved threshold voltage shift (ΔVₜₕ) under NBIS, compared to the transistor thin films according to Comparative Examples. Accordingly, the transistor thin film according to Example exhibits high stability under NBIS, compared to the transistor thin films according to Comparative Examples.

### Evaluation III

HCS (hot carrier stress) effects of the thin film transistors according to Examples and Comparative Examples are evaluated.

HCS condition: VGS=20 V, VDS=20 V

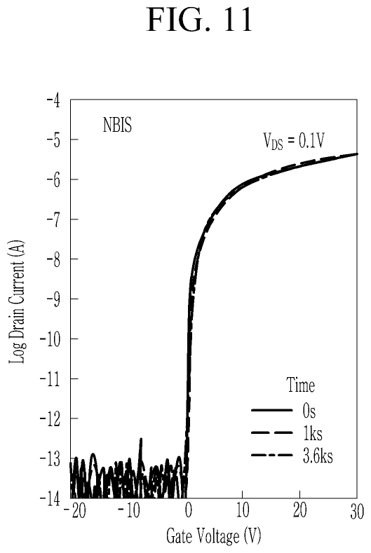

The results are shown in Tables 3 and 4 and FIGS. 11 to 13.

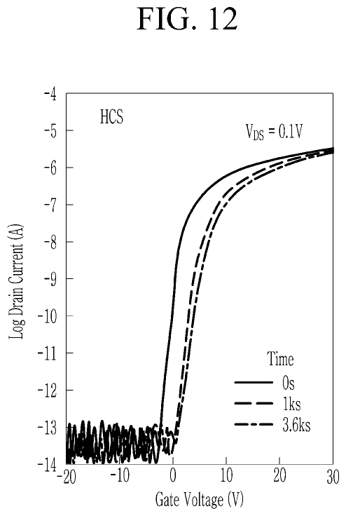

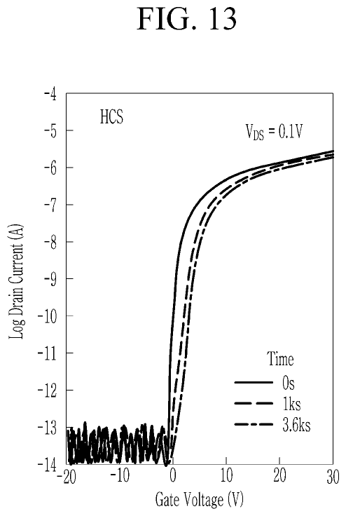

FIG. 11 is a graph showing a transfer curve under HCS of the thin film transistor according to Example 1, FIG. 12 is a graph showing a transfer curve under HCS of a thin film transistor according to Comparative Example 1, and FIG. 13 is a graph showing a transfer curve of a thin film transistor according to Comparative Example 2 under HCS.

TABLE 3

| | SS₀ (V/dec) | SS₁ (V/dec) | ΔSS (V/dec) |
|---|---|---|---|
| Example 1 | 0.27 | 0.28 | 0.01 |
| Comparative Example 1 | 0.45 | 0.61 | 0.16 |
| Comparative Example 2 | 0.80 | 1.05 | 0.25 |

TABLE 4

| | Vₜₕ₀ (V) | Vₜₕ₁ (V) | ΔVₜₕ (V) |
|---|---|---|---|
| Example 1 | 0.8 | 1.2 | 0.4 |
| Comparative Example 1 | −0.9 | 3.2 | 4.1 |
| Comparative Example 2 | 0.4 | 1.4 | 1.0 |

Referring to Tables 3 and 4 and FIGS. 11 to 13, the thin film transistor according to Example exhibits improved changes in the subthreshold swing (ΔSS) and threshold voltage shift (ΔVₜₕ) under HCS, compared with the thin film transistors according to Comparative Examples. Accordingly, the thin film transistor according to Example exhibits high stability under HCS, compared to the thin film transistors according to Comparative Examples.

While this invention has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A method of manufacturing a thin film transistor, comprising
forming a gate electrode,
forming an oxide semiconductor layer at least partially overlapping the gate electrode, and
forming a source electrode and a drain electrode electrically connected to the oxide semiconductor layer,
wherein the forming of the oxide semiconductor layer comprises
forming a first oxide semiconductor layer, and
forming a second oxide semiconductor layer on the first oxide semiconductor layer, the second oxide semiconductor layer having a higher energy bandgap than the first oxide semiconductor layer,
the forming of the second oxide semiconductor layer is performed by a different process from the forming of the first oxide semiconductor layer, and
the forming of the second oxide semiconductor layer comprises spraying a precursor solution for the second oxide semiconductor on the first oxide semiconductor layer followed by heat treatment.

2. The method of claim 1, wherein the forming of the first oxide semiconductor layer is performed by a vapor deposition process.

3. The method of claim 1, wherein the heat treatment is performed at a higher temperature than the forming of the first oxide semiconductor layer.

4. The method of claim 1, wherein the heat treatment is performed at about 250° C. to about 450° C.

5. The method of claim 1, wherein the second oxide semiconductor layer is formed to be thicker than the first oxide semiconductor layer.

6. The method of claim 1, wherein the precursor solution for the second oxide semiconductor comprises a zinc precursor and a tin precursor.

7. The method of claim 1, wherein
the first oxide semiconductor layer is an indium-gallium-zinc oxide layer, and
the second oxide semiconductor layer is a zinc-tin oxide layer.

8. A thin film transistor, comprising
a gate electrode,
an oxide semiconductor layer overlapping the gate electrode,
a gate insulating layer between the gate electrode and the oxide semiconductor layer, and
a source electrode and a drain electrode electrically connected to the oxide semiconductor layer,
wherein the oxide semiconductor layer comprises
first oxide semiconductor layer, and
a second oxide semiconductor layer, the second oxide semiconductor having a higher energy bandgap than the first oxide semiconductor.

9. The thin film transistor of claim 8, wherein
the second oxide semiconductor layer is in contact with an upper surface of the first oxide semiconductor layer, and
the first oxide semiconductor layer and the second oxide semiconductor layer form a heterojunction.

10. The thin film transistor of claim 8, wherein an energy bandgap difference between the second oxide semiconductor layer and the first oxide semiconductor layer is greater than or equal to about 0.20 eV.

11. The thin film transistor of claim 8, wherein a thickness of an interface between the first oxide semiconductor layer and the second oxide semiconductor layer is about 0.1 nm to about 0.5 nm.

12. The thin film transistor of claim 8, wherein the first oxide semiconductor layer is in contact with the gate insulating layer.

13. The thin film transistor of claim 8, wherein the second oxide semiconductor layer is thicker than the first oxide semiconductor layer.

14. The thin film transistor of claim 13, wherein a thickness of the second oxide semiconductor layer is about two or more times greater than a thickness of the first oxide semiconductor layer.

15. The thin film transistor of claim 13, wherein a ratio of the thickness of the first oxide semiconductor layer to the thickness of the second oxide semiconductor layer is about 1:2.5 to about 1:5.

16. The thin film transistor of claim 8, wherein each of the first oxide semiconductor layer and the second oxide semiconductor layer is an amorphous semiconductor layer.

17. The thin film transistor of claim 8, wherein
the first oxide semiconductor layer is an indium-gallium-zinc oxide layer, and
the second oxide semiconductor layer is a zinc-tin oxide layer.

18. A display panel comprising the thin film transistor of claim 8.

19. The display panel of claim 18, wherein the display panel comprises a liquid crystal display panel, an organic light emitting diode display panel, a quantum dot display panel, or a perovskite display panel.

20. A display device comprising the display panel of claim 18.
